(19) United States
(12) Patent Application Publication
(10) Pub. No.: US 2009/0066386 A1
(43) Pub. Date: Mar. 12, 2009

(54) MTCMOS FLIP-FLOP WITH RETENTION FUNCTION

(75) Inventor: Jae Jun LEE, Seoul (KR)

Correspondence Address: Workman Nydegger;1000 Eagle Gate Tower, 60 East South Temple, Salt Lake City, UT, 84111, US

(73) Assignee: DONGBU HITEK CO., LTD., Seoul (KR)

(21) Appl. No.: 12/195,075

(22) Filed: Aug. 20, 2008

(30) Foreign Application Priority Data
Sep. 11, 2007 (KR) 10-2007-0092215

(51) Int. Cl. H03K 3/289

(52) U.S. Cl. 327/202

(57) ABSTRACT

There is provided a MTCMOS flip-flop configured to operate at high speed and to reduce leakage current while realizing a retention function in a sleep mode. The MTCMOS flip-flop may include a signal generator adapted to output an internal clock signal or a sleep mode control signal based on changes in a retention signal and an external clock signal, a master latch adapted to latch an input signal and to output a master latch output signal based on the internal clock signal, and a slave latch connected to an actual ground and adapted to latch the master latch signal, to output a slave latch output signal under control of the internal clock signal, and to maintain the latched signal under control of the sleep mode control signal in the sleep mode.

### CROSS-REFERENCE TO RELATED APPLICATION

This application claims priority to Korean Application No. 10-2007-0092215, filed on Sep. 11, 2007, which is incorporated herein by reference in its entirety.

### BACKGROUND

1. Field of the Invention

Embodiments of the present invention relate to a multi-threshold CMOS (hereinafter, referred to as MTCMOS) flip-flop.

2. Description of Related Art

As the processes of semiconductor circuits are reduced to units no less than 100 μm, reducing leakage current becomes a larger problem than reducing dynamic power loss. In addition, demand in the market is increasing for a high performance portable apparatus. In order to satisfy such product design and market conditions, a large number of companies try to design semiconductor circuits that consume a small amount of power. MTCMOS technology is most widely used for designing the semiconductor circuits that consume a small amount of power.

The core of an MTCMOS circuit may be designed using low threshold voltage (Low-Vth) CMOS transistors so that the performance of the MTCMOS circuit is improved. A switch using a high threshold voltage (High-Vth) CMOS transistor may be connected between the core and a power voltage or between the core and an actual ground line. The High-Vth switch is turned off in a sleep mode of the MTCMOS circuit to reduce leakage current. Implementing the High-Vth switch between the core and the power voltage is referred to as a header method as shown in FIG. 1A and implementing the High-Vth switch between the ground line and the core is referred to as a footer method as shown in FIG. 1B.

For example, in the MTCMOS circuits illustrated in FIG. 1, a header or footer cell having the High-Vth switch is turned on when the circuit is used so that the Low-Vth core is driven to operate the circuit and the header or footer cell having the High-Vth switch is turned off when the circuit is not used so that the leakage current of the circuit is reduced. The header cell having the High-Vth switch connects a power voltage source Vdd to a virtual power voltage source Vddv of a Low-Vth logic circuit and the footer cell connects an actual ground Vss to a virtual ground Vssv.

A flip-flop in a master slave configuration is a representative circuit in which an MTCMOS circuit may be used.

In the conventional master slave configured flip-flop, as illustrated in FIG. 2, a Low-Vth transistor is used in the core and a High-Vth transistor is used as a switch in the footer cell so that the flip-flop is operated at high speed and leakage current is reduced.

Referring to FIG. 2, the master slave flip-flop includes a master latch 200, a slave latch 250, and a clock signal generator 260 for providing internal clock signals to the logic devices of the master latch 200 and the slave latch 250. The logic devices are switched using a footer cell 270.

During operation of the master slave flip-flop, when the external clock signal CLK of the clock signal generator 260 is at a high level, a high signal is output to a first signal line 1 and a low signal is output to a second signal line 2. Therefore, the master latch 200 receives input data D, that is, an input signal to be latched, and the slave latch 250 receives a previous logic stage to output the same.

On the other hand, when the clock signal CLK of the clock signal generator 260 is at a low level, the low signal is output to the first signal line 1 and the high signal is output to the second signal line 2. Therefore, a previous signal is latched by the master latch 200 and the slave latch 250 latches the signal received from the master latch 200 and outputs the previously latched signal as an output signal Q.

As described above, when a flip-flop implemented with a MTCMOS switch transitions from a normal operation mode to a sleep mode, the MTCMOS switch is turned off and the contents stored in the flip-flop are lost or erased. Therefore, when a transition to a normal operation mode is then made, restoration to a previous state is not performed. In order to solve such problems, a retention flip-flop may be used.

FIG. 3 is a circuit diagram illustrating the conventional master slave flip-flop having a retention function.

Referring to FIG. 3, the conventional master slave flip-flop having the retention function may additionally include a retention latch 300 for maintaining data when the master slave flip-flop of FIG. 2 is transitioned to the sleep mode. When the master slave flip-flop is transitioned to the sleep mode, power is continuously supplied to the retention latch 300.

The conventional master slave flip-flop having the retention function is transitioned to the sleep mode after storing the value of the slave latch 250 in the retention latch 300. Therefore, although the data of the master latch 200 is lost, the data stored in the retention latch 300 is maintained since the power of the retention latch 300 is continuously supplied. When the master slave flip-flop is transitioned to a normal operation mode, the data of the retention latch 300 is transmitted to the slave latch 250 to be restored to an original state.

The conventional master slave flip-flop having the retention function includes a control signal generator 310 for generating control signals to be applied to the MTCMOS device for connecting the slave latch 250 and the retention latch 300 to each other in a sleep mode or standby state. Control signals may include signals a and b, generated by the control signal generator 310, and control signals c and d, generated by a retention signal generator 320. The conventional master slave flip-flop having the retention function may also include the clock signal generator 260 for generating clock signals.

### SUMMARY OF SOME EXAMPLE EMBODIMENTS

As described above, the conventional master slave flip-flop having the retention function must generate various control signals in order to realize the retention function and has a logic burden of performing various controls in accordance with the control signals.

In general, example embodiments of the present invention relate to an MTCMOS flip-flop having a retention function capable of generating a sleep mode control signal in a sleep mode and an internal clock signal based on a retention signal and an external clock signal to realize the retention function.

In accordance with a first embodiment, there is provided an MTCMOS flip-flop having a retention function, comprising a signal generator adapted to output an internal clock signal or a sleep mode control signal based on changes in a retention signal and an external clock signal, a master latch adapted to latch an input signal and to output a master latch output signal based on the internal clock signal, and a slave latch connected to an actual ground and adapted to latch the master latch signal, to output a slave latch output signal under control of the internal clock signal, and to maintain the latched signal under control of the sleep mode control signal in a sleep mode.

In accordance with a second embodiment, there is provided an MTCMOS flip-flop having a retention function, comprising a signal generator adapted to output an internal clock signal or a sleep mode control signal based on changes in a retention signal and an external clock signal, a master latch adapted to latch an input signal and to output a master latch output signal based on the internal clock signal and to output a low signal based on an external reset signal, and a slave latch connected to an actual ground and adapted to latch the master latch signal, to output a slave latch output signal under control of the internal clock signal, to maintain the latched signal under control of the retention control signal, and to output a uniform output signal based on the reset signal in a sleep mode.

According to embodiments of the present invention, signals required for the sleep mode and normal operation mode may be provided using a NAND gate, in which the external clock signal and the retention signal are used as inputs, and an inverter so that it is possible to operate the MTCMOS flip-flop at high speed, to reduce leakage current, and to realize the retention function in the sleep mode.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter.

Additional features will be set forth in the description which follows, and in part will be obvious from the description, or may be learned by the practice of the teachings herein. Features of the invention may be realized and obtained by means of the instruments and combinations particularly pointed out in the appended claims. Features of the present invention will become more fully apparent from the following description and appended claims, or may be learned by the practice of the invention as set forth hereinafter.

### BRIEF DESCRIPTION OF THE DRAWINGS

Aspects of example embodiments of the invention will become apparent from the following description of example embodiments given in conjunction with the accompanying drawings, in which:

FIGS. 1A and 1B illustrate a conventional header cell configuration and a conventional footer cell configuration.

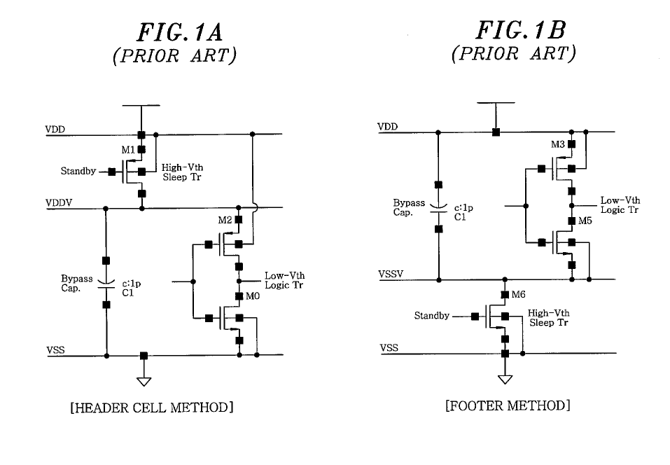

FIG. 2 is a circuit diagram illustrating a conventional MTCMOS flip-flop.

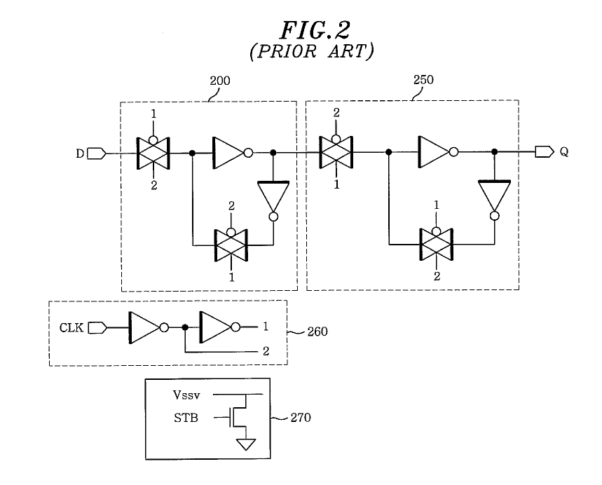

FIG. 3 is a circuit diagram illustrating the conventional MTCMOS flip-flop having a retention function.

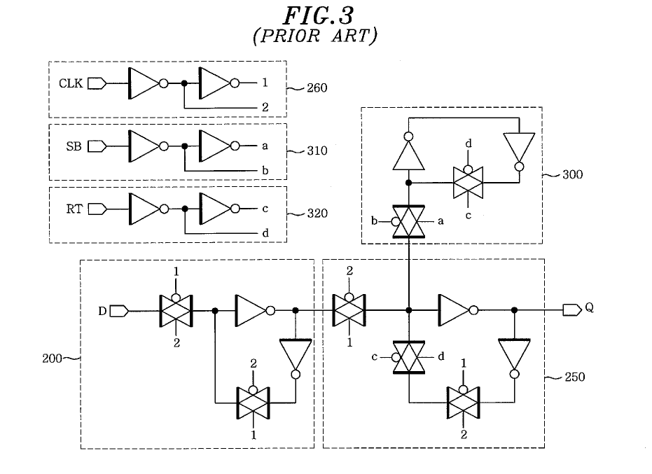

FIG. 4 is a circuit diagram illustrating a MTCMOS flip-flop having a retention function according to an embodiment of the present invention.

FIG. 5 illustrates a footer cell applied to a master latch according to an embodiment of the present invention.

FIG. 6 illustrates an internal circuit of a signal generator according to an embodiment of the present invention.

FIG. 7 illustrates a circuit of a MTCMOS flip-flop having a retention function according to another embodiment of the present invention.

FIG. 8 illustrates signals output during normal and sleep mode operations according to embodiments of the present invention.

### DETAILED DESCRIPTION OF SOME EXAMPLE EMBODIMENTS

In the following detailed description of the embodiments, reference is made to the accompanying drawings that show, by way of illustration, specific embodiments of the invention. In the drawings, like numerals describe substantially similar components throughout the several views. These embodiments are described in sufficient detail to enable those skilled in the art to practice the invention. Other embodiments may be utilized and structural, logical and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. Furthermore, when it is determined that detailed description of a well-known structure or function can obscure understanding, detailed description thereof will be omitted. The following detailed description is, therefore, not to be taken in a limiting sense, and the scope of the present invention is defined only by the appended claims, along with the full scope of equivalents to which such claims are entitled.

According to embodiments of the present invention, a sleep mode control signal and an internal clock signal may be generated using a NAND gate and an inverter, and a slave latch may be connected to an actual ground so that a retention function can be performed using the slave latch in a sleep mode.

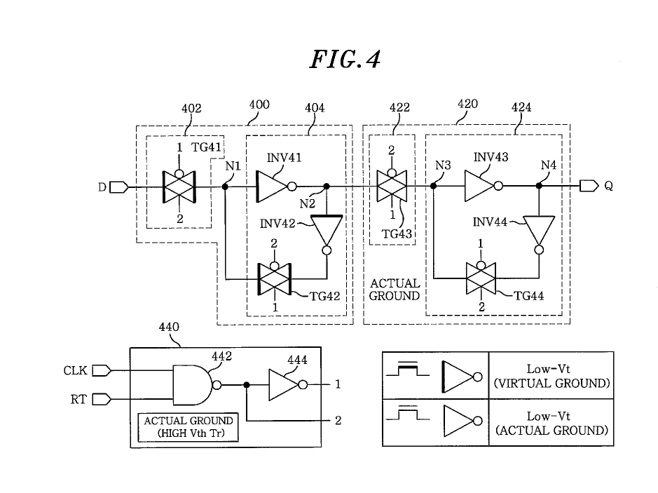

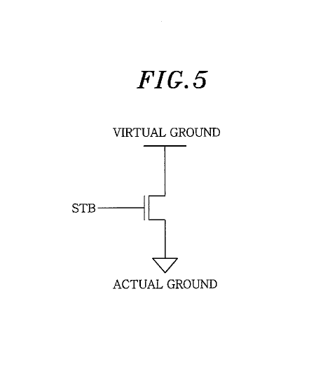

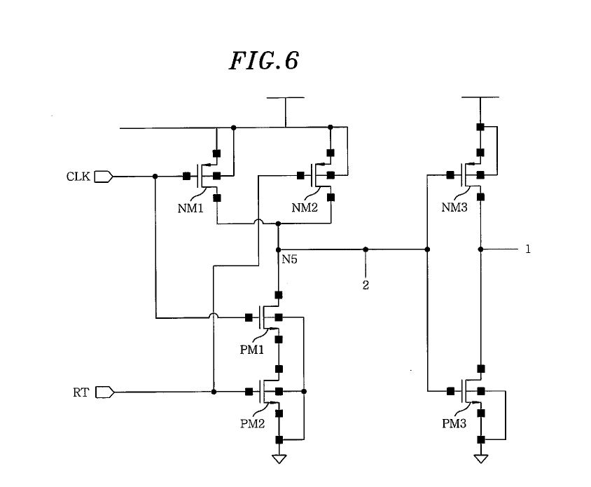

FIG. 4 is a circuit diagram illustrating an exemplary MTCMOS flip-flop having a retention function according to a first embodiment. FIG. 5 illustrates a footer cell that may be applied to a master latch in an exemplary MTCMOS flip-flop. FIG. 6 illustrates an internal circuit of a signal generator in an exemplary MTCMOS flip-flop.

Referring to FIG. 4, the exemplary MTCMOS flip-flop circuit may include a master latch 400, a slave latch 420, and a signal generator 440. The master latch 400 may include a plurality of logic devices driven at a Low-Vth that are connected to an actual ground line through the footer cell illustrated in FIG. 5. The footer cell may be driven at a High-Vth. The slave latch 420 may include a plurality of logic devices that are driven at the Low-Vth and that are grounded to the actual ground line (i.e., not through the footer cell). The signal generator 440 may be adapted to output an internal clock signal or a sleep mode control signal using an external clock signal and a retention signal as inputs.

The signal generator 440 may generate internal clock signals including an inverted internal clock signal and an internal clock signal based on the external clock signal CLK and the retention signal RT, and may output the generated internal clock signals to first and second signal lines. The inverted internal clock signal and the internal clock signal output through the first and second signal lines may be received by the logic devices of the master latch 400 and the slave latch 420 to control the turning on and off of the logic devices.

The signal generator 440 may include a NAND gate 442 for receiving the external clock signal CLK and the retention signal RT as inputs and may include an inverter 444 for inverting the output of the NAND gate 442. The output of the NAND gate 442 may correspond to the second signal line and an output of the inverter 444 may correspond to the first signal line.

As illustrated in FIG. 6, the NAND gate 442 of the signal generator 440 may include first and second NMOS transistors NM1 and NM2, to which the external clock signal CLK and the retention signal RT are input, and first and second PMOS transistors PM1 and PM2, to which the external clock signal CLK and the retention signal RT are input. The inverter 444 may include a third PMOS transistor PM3 and a third NMOS transistor NM3. The first and second NMOS transistors NM1 and NM2 may be connected to each other in parallel such that a power source is applied to one end of each of the first and second NMOS transistors NM1 and NM2 and the other end of each of the first and second NMOS transistors NM1 and NM2 is connected to a node N5. The first and second PMOS transistors PM1 and PM2 may be serially connected to each other such that one end of the serially connected PMOS transistors PM1 and PM2 is applied to the actual ground and the other end of the serially connected PMOS transistors PM1 and PM2 is connected to the node N5. The signal output through the node N5 may correspond to the second signal line of the signal generator 440. The signal output through the node N5 may also be input to the third NMOS transistor NM3 and the third PMOS transistor PM3 of the inverter 444 to be inverted and output on the first signal line of the signal generator 440.

During a normal mode of operation the retention signal input to the signal generator 440 may be set at a high level so that the master latch 400 and the slave latch 420 of the MTCMOS flip-flop will normally operate in accordance with a change in the external clock signal CLK.

In addition, during a sleep mode, the retention signal RT may be set at a low level and the footer cell connected to the logic devices of the master latch 400 may be turned off. As a result, the signal generator 440 outputs a low signal (that is, 0) to the first signal line and a high signal (that is, 1) to the second signal line regardless of the input of the external clock signal CLK.

The master latch 400 may include a latch gate 402 and a master latch circuit 404. The latch gate 402 may include a transmission gate TG41 for transmitting input signals D to a first node N1 under control of the internal clock signal and the inverted internal clock signal input through the first and second signal lines, respectively, of the signal generator 440. The master latch circuit 404 may receive the output signal of the master latch gate 402 to output the received output signal to a second node N2.

The master latch circuit 404 may include an inverter INV41, an inverter INV42, and a transmission gate TG42. The inverter INV41 may be adapted to receive and invert the output signal of the first node N1 to output the inverted output signal to the second node N2. The inverter INV42 may be adapted to receive and invert the signal of the second node N2. The transmission gate TG42 may be adapted to receive the output signal of the inverter INV42 under the control of the internal clock signal and the inverted clock signal to transmit the received output signal to the first node N1.

One or more of the transmission gates TG41 and TG42 and the inverters INV41 and INV42 in the master latch 400 may be connected to the footer cell to be grounded to the actual ground. The footer cell may be switched off in the sleep mode by a standby signal STB, e.g., a low voltage signal, to break a connection between a virtual ground and an actual ground so that the Low-Vth transistors of the transmission gates TG41 and TG42 are floated.

The slave latch 420 may include a slave latch gate 422 comprising a transmission gate TG43 for receiving the signal of the second node N2 under control of the internal clock signal and the inverted internal clock signal. The transmission gate TG43 may transmit the signal received from node N2 to a third node N3 in a slave latch circuit 424. The slave latch circuit 424 may receive and latch the output signal of the slave latch gate 422 to output the latched output signal to a fourth node N4.

The slave latch circuit 424 may include an inverter INV43, an inverter INV44, and a transmission gate TG44. The inverter INV43 may be adapted to receive and invert the signal of the third node N3 and to output the inverted signal to a fourth node N4. The inverter INV44 may be adapted to receive and invert the signal of the fourth node N4. The transmission gate TG44 may be adapted to receive the output signal of the inverter INV44 under control of the internal clock signal and the inverted internal clock signal to transmit the received output signal to the third node N3.

Low-Vth transistors in the slave latch 420 may be connected to the actual ground in order to perform the retention function in the sleep mode. That is, since the retention signal RT is set at a low level in the sleep mode, the low signal is output to the first signal line and the high signal is output to the second signal line regardless of the external clock signal CLK. Therefore, since the transmission gate TG44 is turned on, the slave latch 422 maintains its current state, that is, the retention state. On the other hand, since the standby signal STB applied to the footer cell of the master latch 400 in the sleep mode is transitioned to the low signal so that the footer cell is turned off, the Low-Vth transistors in the transmission gates TG41 and TG42 are floated so that the master latch 400 does not operate and thus the leakage current of the master latch 400 is reduced.

Processes of operating a flip-flop circuit having the above structure will now be described. Processes of transitioning the data of the flip-flop in a normal operation mode are first described, then sleep mode processes are described.

In the normal operation mode, since the sleep mode control signal is set at a high level, the output of the signal generator 440, that is, the output signals of the first and second signal lines are changed by the external clock signal CLK. When the external clock signal CLK is in the low level, since the output signal of the first signal line is in the low level and the output signal of the second signal line is in the high level, the transmission gates TG41 and TG44 are turned on and the transmission gates TG42 and TG43 are turned off. Thus a change in input data D is transmitted only to the second node N2 of the master latch 400 and a data value in a previous state is latched by and output from the slave latch 420. When the external clock signal CLK is transitioned to a high level, since the output signal of the first signal line is in the high level and the output signal of the second signal line is in the low level, the transmission gates TG41 and TG44 are turned off and the transmission gates TG42 and TG43 are turned on so that the signal of the second node N2 before the external clock signal CLK was transitioned to the high level is latched by the master latch 400 and is output as the output data Q of the flip-flop through the transmission gate TG43 and the inverter INV43.

On the other hand, in the sleep mode, the master latch 400 does not operate since the retention signal RT and the standby signal STB applied to the footer cell are each transitioned to a low level at the same time. In particular, because the retention signal RT is low, a low signal is output to the first signal line and a high signal is output to the second signal line regardless of the external clock signal CLK. Furthermore, when the standby signal STB is transitioned to a low level, the footer cell connected to the transmission gates TG41 and TG42 and the inverters INV41 and INV42 of the master latch 400 is turned off so that the master latch 400 does not actually operate.

In addition, since the Low-Vth transistors in the transmission gates TG43 and TG44 and the inverters INV43 and INV44 of the slave latch 420 are connected to the actual ground, the transmission gates TG43 and TG44 and the inverters INV43 and INV44 of the slave latch 420 operate without being affected by the standby signal STB. That is, the transmission gate TG44 is turned on and the transmission gate TG43 is turned off based on the output signals output from the first and second signal lines to maintain the previous state, that is, the retention state.

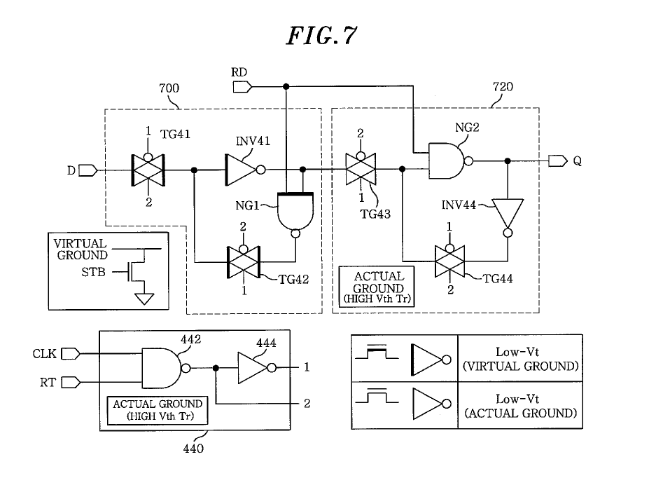

FIG. 7 illustrates a circuit of a MTCMOS flip-flop having a retention function according to another embodiment.

Referring to FIG. 7, a MTCMOS flip-flop circuit may control a master latch 700 and a slave latch 720 in the sleep mode and the normal operation using the signal generator 440 illustrated in FIG. 6 and may fix the output signal Q to a high level when a reset is required by a reset signal RD.

Therefore, a first NAND gate NG1 to which the reset signal RD is applied may be provided in the master latch 700 instead of the inverter INV42 of the master latch 400 illustrated in FIG. 4. Like the inverter INV42, the first NAND gate NG1 may be connected to the footer cell to be grounded to the actual ground and may operate using the signal of the second node N2 and the reset signal RD as inputs.

In addition, a second NAND gate NG2 to which the reset signal RD is applied may be provided in the slave latch 720 instead of the inverter INV43 of the slave latch 420 illustrated in FIG. 4. The second NAND gate NG2 may be connected to the actual ground and may operate using the signal of the third node N3 and the reset signal RD as inputs.

In the normal operation mode, the reset signal RD may be set at a high level and may be transitioned to a low level in a reset operation mode.

That is, in the normal operation mode, when the reset signal RD is at the high level, the first NAND gate NG1 inverts and outputs the output signal of the second node N2 and the second NAND gate NG2 inverts the signal of the third node N3 to output the inverted signal to the fourth node N4.

In the reset operation mode, on the other hand, the reset signal RD is at a low level. As a result, the second NAND gate NG2 outputs a high signal, i.e., a signal of 1, as the output signal Q regardless of the signal of the third node N3.

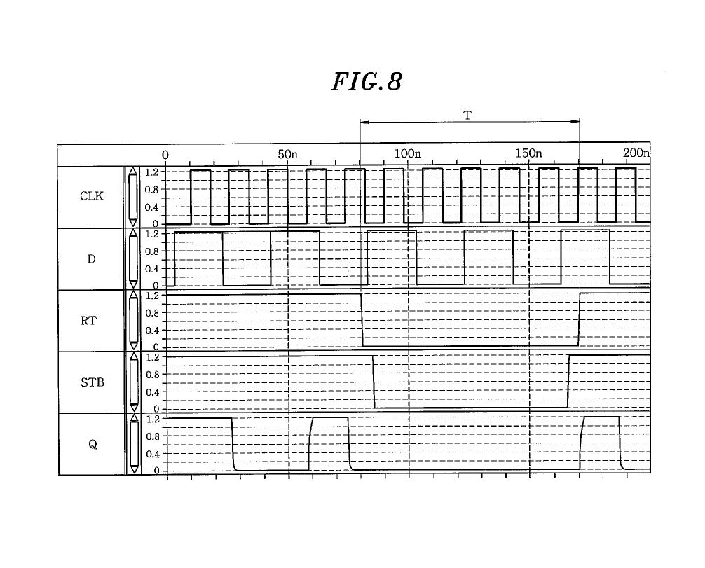

As illustrated in FIG. 8, in a flip-flop implemented according to the exemplary structures described above, it is noted that the output signal Q maintains the previous state regardless of a change in an input signal in a sleep mode period T and that during a normal operation mode the output signal Q is changed based on the change in the input signal.

While the present invention has been described with respect to the preferred embodiment, it will be apparent to those skilled in the art that various changes and modifications may be made without departing from the scope of the present invention as defined in the following claims.

What is claimed is:

1. A MTCMOS flip-flop comprising:
a signal generator adapted to output an internal clock signal or a sleep mode control signal based on changes in a retention signal and an external clock signal;
a master latch adapted to latch an input signal and to output a master latch output signal based on the internal clock signal; and
a slave latch connected to an actual ground and adapted to latch the master latch signal, to output a slave latch output signal under control of the internal clock signal, and to maintain the latched signal under control of the sleep mode control signal in a sleep mode.

2. The MTCMOS flip-flop of claim 1, wherein the signal generator comprises:
a NAND gate using the retention signal and the external clock signal as inputs; and
an inverter for inverting an output signal of the NAND gate.

3. The MTCMOS flip-flop of claim 2, wherein at least one of the internal clock signal and the sleep mode control signal is an output of at least one of the NAND gate and the inverter.

4. The MTCMOS flip-flop of claim 2, wherein the NAND gate includes two parallel connected NMOS transistors connected in series to two serially connected PMOS transistors, and wherein the external clock signal and the retention signal are applied to the PMOS transistors and the NMOS transistors.

5. The MTCMOS flip-flop of claim 1, wherein the master latch comprises:
a master latch gate turned on or off under control of the internal clock signal to output the input signal to a first node;
a first inverter adapted to invert a signal of the first node to output the inverted signal to a second node;
a second inverter adapted to receive a signal of the second node to invert the received signal; and
a first transmission gate adapted to output a signal of the second inverter to the first node under control of the internal clock signal,
wherein the master latch gate, the first and second inverters, and the transmission gate are floated by a footer cell turned off in a sleep mode.

6. The MTCMOS flip-flop of claim 5, wherein the slave latch comprises:
a slave latch gate adapted to transmit the signal of the second node to a third node under control of the internal clock signal or to be turned off based on the sleep mode control signal;
a third inverter adapted to receive and invert the signal of the third node to output the inverted signal to a fourth node;
a fourth inverter adapted to receive and invert the signal of the fourth node; and
a second transmission gate adapted to output the signal of the fourth inverter to the third node under control of the internal clock signal or the retention control signal,
wherein the slave latch gate, the third and fourth inverters, and the second transmission gate are connected to an actual ground.

7. A MTCMOS flip-flop comprising:
a signal generator adapted to output an internal clock signal or a sleep mode control signal based on changes in a retention signal and an external clock signal;
a master latch adapted to latch an input signal, to output a master latch output signal based on the internal clock signal, and to output a low signal based on an external reset signal; and
a slave latch connected to an actual ground and adapted to latch the master latch signal, to output a slave latch output signal under control of the internal clock signal, to maintain the latched signal under control of the retention control signal, and to output a uniform output signal based on the reset signal in a sleep mode.

8. The MTCMOS flip-flop of claim 7, wherein the signal generator comprises:
a NAND gate using the retention signal and the external clock signal as inputs; and
an inverter for inverting the output signal of the NAND gate.

9. The MTCMOS flip-flop of claim 8, wherein at least one of the internal clock signal and the sleep mode control signal is an output of at least one of the NAND gate and the inverter.

10. The MTCMOS flip-flop of claim 8, wherein the NAND gate includes two parallel connected NMOS transistors connected in series to two serially connected PMOS transistors, and wherein the external clock signal and the retention signal are applied to the PMOS transistors and the NMOS transistors.

11. The MTCMOS flip-flop of claim 7, wherein the master latch comprises:
a master latch gate turned on or off under control of the internal clock signal to output the input signal to a first node;
a first inverter adapted to invert a signal of the first node to output the inverted signal to a second node;
a first NAND gate adapted to invert a signal of the second node or to output a high signal using the signal of the second node and the reset signal as inputs; and
a first transmission gate adapted to output a signal of the first NAND gate to the first node under control of the internal clock signal,
wherein the master latch gate, the first inverter, the first NAND gate, and the transmission gate are floated by a footer cell turned off in a sleep mode.

12. The MTCMOS flip-flop of claim 11, wherein the slave latch comprises:
a slave latch gate adapted to transmit the signal of the second node to a third node under control of the internal clock signal or to be turned off based on the retention control signal;
a second NAND gate adapted to invert a signal of the third node to output the inverted signal to a fourth node or to output a high signal as an output signal using the signal of the third node and the reset signal as inputs;
a second inverter adapted to receive and invert a signal of the fourth node; and
a second transmission gate adapted to output the signal of the second inverter to the third node under control of the internal clock signal or the retention control signal,
wherein the slave latch gate, the second inverter, the second NAND gate, and the second transmission gate are connected to an actual ground in the sleep mode.

13. The MTCMOS flip-flop of claim 1, wherein the master latch is connected to a virtual ground, the virtual ground being switchably connected to the actual ground based on the sleep mode control signal.

14. The MTCMOS flip-flop of claim 7, wherein the master latch is connected to a virtual ground, the virtual ground being switchably connected to the actual ground based on the sleep mode control signal.
